(19) United States
(12) Patent Application Publication
(10) Pub. No.: US 2003/0209431 A1
(43) Pub. Date: Nov. 13, 2003

(54) Magnetron sputtering source with improved target utilization and deposition rate

(76) Inventor: Jeffrey T. Brown, Rocklin, CA (US)

Correspondence Address: Richard L Byrne, 700 Koppers Building, 436 Seventh Avenue, Pittsburgh, PA, 15219-1818, US

(21) Appl. No.: 10/257,165

(22) PCT Filed: Apr. 10, 2001
(86) PCT No.: PCT/US01/11780

(51) Int. Cl. C23C 14/35

(52) U.S. Cl. 204/298.19; 204/298.09

(57) ABSTRACT

A magnetron sputtering cathode (21) having a simplified design provides excellent target (56) utilization. The magnet design contains three or four magnet sets (50, 52, 54). These magnets (50, 5254) are behind a heat shield capable of removing about 500 watts per square unit, such as inches. All the magnet sets (50, 52, 54) have magnetic orientations substantially perpendicular to the magnet base plate. The magnetic orientation of the center magnet (50) is north up; the second magnet array is south up (52); the third magnet set is south up (54); and the fourth magnet set, it used, is north up. The magnet arrays are easier to assemble and repair and produce a target utilization of at least 30 percent and preferably 40 percent or higher.

### BACKGROUND OF THE INVENTION

1. Field of the Invention

The present invention relates to sputtering devices used in vacuum systems and, more particularly, to sputtering devices which are magnetically enhanced.

2. Brief Description of the Prior Art

Sputtering devices are used to deposit a target material onto a substrate. The target material is typically a planar sheet of aluminum, gold, or other material that is connected to a cathode, eroded by ionized plasma in a vacuum, and vapor deposited onto the substrate.

In order to increase material removal, ionization of the plasma is improved by the use of magnetic fields to confine the electrons. These sputtering devices are called magnetron cathodes. One of the primary problems associated with magnetron sputter deposition is that the target material erodes non-uniformly. Ideally, the target material should erode uniformly with respect to one side of the target, resulting in high utilization of the material in the target. Utilization is defined as the percentage of material (by weight) removed from the target during sputtering. However, the sputtering process generally forms one or more erosion troughs, typically V-shaped, on one side of the target, when the target is viewed in cross section, with more target material being removed from a center of the trough than at a perimeter of the trough. The trough extends deeper into the target material as target material erodes until a hole develops in the target material. Once a hole forms in the target material, usually near the center of the trough, the target material must be removed, and a new target must be connected to the cathode. Continuous replacement of the target material reduces production time, which is increased because the sputtering target is located in a vacuum chamber and must be re-evacuated after each target change. Moreover, the remaining or remnant target material may need to be salvaged and reprocessed, particularly if the target is made from a precious metal. This reclamation of material results in higher economic costs.

Efforts have been made to increase uniform target erosion and utilization in magnetron sputtering devices, such as those disclosed in U.S. Pat. Nos. 4,461,688; 5,262,028; or 4,282,083. The general concept of the prior art arrangements is to generate magnetic fields that trap electrons which ionize argon, forming plasma, and distributing the plasma ions linearly over a surface of the target material. Depending on the orientation of the magnets used, a two-magnet configuration generally produces three magnetic trapping regions, and a three-magnet configuration generally produces four magnetic trapping regions. The two-magnet configuration typically has only one of the three magnet trapping regions within the plasma. These magnetic trapping regions confine the plasma and form erosion troughs in the target material.

Despite the advances of the prior art, a trade-off exists. Devices with higher target material utilization often require a large number of expensive, complex-shaped magnet arrays. Some of these magnet arrays are positioned in close proximity to each other, with neighboring magnet arrays aligned in common polarity. For example, a first magnet array with a north-south polarity and a second magnet array with a north-south polarity are oriented with their respective south poles, adjacent the magnetic base. The natural magnetic repulsion between the like polarities of the first and second magnetic arrays push the arrays apart during installation or repair, making installation or repair more difficult. This problem is magnified if the second array is made up of small based, tall, rectangular, individual magnets loosely assembled in a ring or oval shape, and a first array is made up of larger magnets. The mass and magnetic attraction to the baseplate of each individual magnet in the second array is not great enough to significantly resist movement caused by the material magnet repulsive forces between the first and second magnet arrays.

The prior art cathodes also do not specifically enable the exact magnetic configuration required to produce the results quoted. Cathode size, magnetic material, and magnet shape all play important rolls in the behavior of the magnetic field. Some previous designs also do not allow room for the balancing of magnetic fields to produce the magnetic flux patterns described within the patent. The prior art also fails to discuss the fields required, or the effect that changing field strengths have on electrons. In some of the prior art, it is unclear what size and strength the inner set of magnets should be that are magnetized parallel to the target. These inner magnets, which are also shown has a fully-packed set of magnets, allow no room to compensate for changes in strength between magnet lots, and makes it difficult to manufacture since neither pole is attached to the magnetic base plate. This requires some adhesive to keep the magnets in position on the plate, or machined features on the magnet plate, increasing the cost, time, and steps to manufacture the cathodes.

Numerous magnetic designs created previously have erroneous or misleading magnetic field line maps. These designs were produced prior to the advanced magnetic modeling now available today.

Therefore, a need exists for a fully-enabled magnetron sputtering device that is easier and less expensive to manufacture, yet is still capable of producing a high-target utilization of at least 30 percent and preferably approximately 40 percent or more with a detailed design specification for the magnetic field.

### SUMMARY OF THE INVENTION

In an effort to overcome the known deficiencies in the prior art, a magnetron sputtering device according to the present invention generally includes a first mounting flange, a second mounting flange, and a cathode having a magnet configuration.

One possible configuration for a magnetron sputtering device according to the present invention includes a target having a free surface, a bottom, and a useable lifetime. A magnet base having a perimeter is preferably positioned adjacent to the target. A first magnet array may be positioned adjacent to the magnet base, a second magnet array may be positioned adjacent to the first magnet array, and a third magnet array may be positioned adjacent to the second magnet array. The first, second, and third magnet arrays may each have a north polarity and an opposite south polarity.

The south polarity of the first magnet array may be positioned adjacent to the magnet base, the north polarity of the second magnet array may be positioned adjacent to the magnet base, and the north polarity of the third magnet array may be positioned adjacent to the magnet base.

The magnet base preferably has a magnetic permeability greater than one and forms a magnetic return which further forms a magnetic pattern of flux lines and field strengths forming closed magnetic loop regions. The magnetic pattern may include a first closed magnetic loop region formed between the first magnet array and the second magnet array, a second closed magnetic loop region formed between the first magnet array and the third magnet array, a third closed magnetic loop region formed between the second magnet array and the magnetic return, a fourth closed magnetic loop region formed between the third magnet array and the magnetic return, and a first magnetic field region formed by the transitions between the magnetic loop regions which forms a null point located near or below a free surface of the target and an end of the useful lifetime of the target. If desired, a fourth magnet array having a north polarity and an opposite south polarity, with the south polarity positioned adjacent to the magnet base, can also be added.

It is, therefore, an object of the present invention to provide a magnetron sputtering device that is easier and less expensive to manufacture and repair, with superior heat dissipation, yet is still capable of producing a high-target material utilization.

These and other advantages of the present invention will be clarified in the Detailed Description of the Preferred Embodiments taken together with the attached drawings in which like reference numerals represent like elements throughout.

### BRIEF DESCRIPTION OF THE DRAWINGS

FIG. 1 is a cross-sectional, first side view of a first embodiment magnetron sputtering device including a cathode, a first mounting flange, a second mounting flange, and a magnet array configuration with a power source passing through the first mounting flange and connecting to the cathode;

FIG. 2 is a cross-sectional, second side view of the cathode, first mounting flange, and magnet array configuration shown in FIG. 1, with coolant orifices extending from the first mounting flange to a coolant well adjacent a target;

FIG. 3 is a simplified cross-sectional, side view of the cathode and magnet array configuration shown in FIGS. I and 2;

FIG. 4 is a cross-sectional, side view of the magnet array configuration shown in FIG. 3;

FIG. 5 is a top view of the magnet array configuration shown in FIGS. 1-4;

FIG. 6 is a plot of the magnetic fields produced by the magnet array configuration shown in FIGS. 1-5;

FIG. 7a is a plot of the magnetic field components parallel (Br) and perpendicular (Bz) to the free surface and the resulting erosion pattern for a 4 unit cathode;

FIG. 7b is a graph of the magnetic field components shown in FIG. 7a except for a 7 unit cathode;

FIG. 8 is a simplified, cross-sectional view of a magnet array configuration according to a second embodiment of the present invention; and

FIG. 9 is a plan view of a possible embodiment for the magnet array for a 7 unit cathode.

### DETAILED DESCRIPTION OF THE PREFERRED EMBODIMENTS

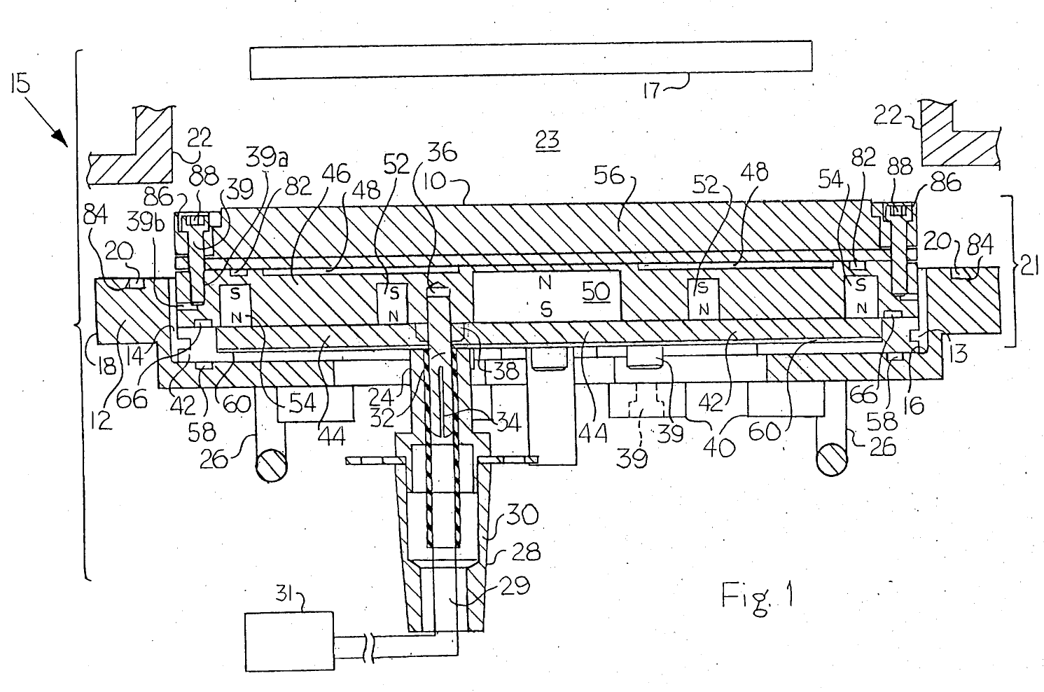

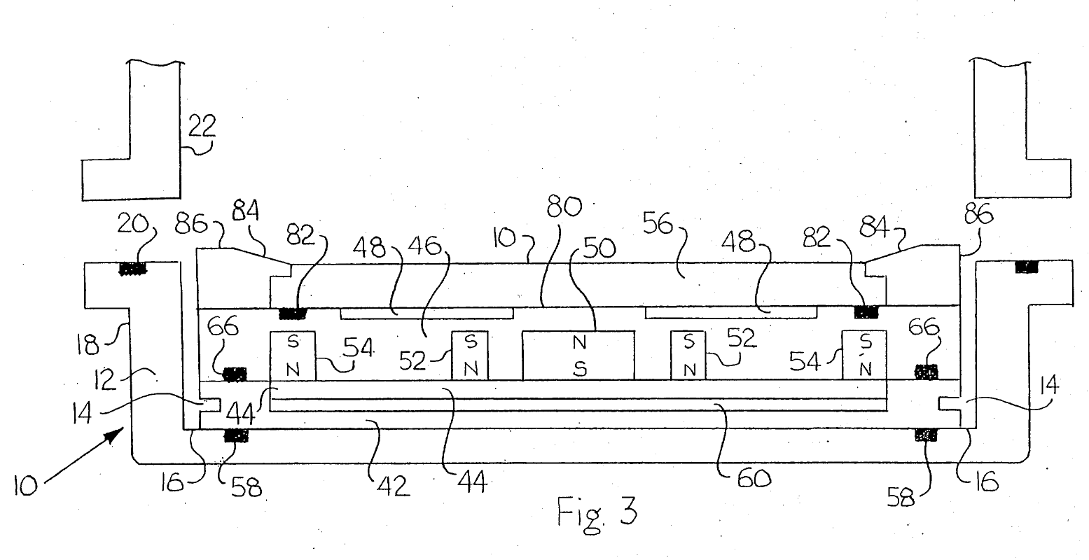

A first embodiment of a magnetron sputtering device 15 in accordance with the present invention is shown in FIGS. 1-6, 7a, 7b, and 9.

The magnetron sputtering device 15 may be either a round or a linear source. A linear source is typically a rectangular cathode for use with large flat sheets or panels, which generate a generally oval-shaped erosion pattern. The round cathode will be described for simplicity. Moreover, the terms unit or units are herein defined as units of measurement, such as inches or other suitable scale.

As shown in FIG. 1, the magnetron sputtering device 15 includes a generally circular-shaped mounting flange 12, a vacuum chamber mounting flange 22, and a cathode 21. The mounting flange 12 contains a recess 13 to position a free surface 10 of a target 56 at a predetermined location within the vacuum chamber mounting flange 22, creating an internal cavity 14, an internal surface 16, and an external surface 18. The vacuum chamber mounting flange 22 houses a substrate 17 to be coated. A first sealing member 20 is positioned between the mounting flange 12 and the vacuum chamber mounting flange 22 in a dovetail-shaped circumferential slot 84. When the mounting flanges 12, 22 are connected and compressed, the mounting flange 12, vacuum chamber mounting flange 22, and first sealing member 20 form an airtight seal. The dovetail slot 84 holds the first sealing member in place during disassembly. The mounting flange 12 preferably forms a vacuum seal with the vacuum chamber mounting flange 22, allowing a pressure ratio of approximately 106 torr when attached to an appropriate chamber.

The free surface 10 of the target 56 is defined as the original or partially-eroded top surface upon which the sputtering process takes place. The original, free surface may be either flat or shaped. The profile of this free surface 10 is constantly changing throughout the operational lifetime of each target 56. Different target materials will generate slightly different eroded, free surfaces 10 due to differences in material sputtering yield. In the prior art, the free surface 10 would normally yield a “V-” or preferably “U-” shaped trench. For the same depth, the erosion profile of the present invention is wider. The end of target life is reached when the target 56 can no longer support the structural loads, such as cooling fluid pressure, or if the sputtering process penetrates the full target 56 thickness, thereby sputtering an underlying cooling well 46, discussed below. In this embodiment, the preferred end of target 56 life for a ⅝ unit thick, 7 unit diameter solid aluminum target 56 is approximately 420 kWh when the minimum target 56 thickness is reduced to 0.06 units; this results in a material utilization of 42.6%.

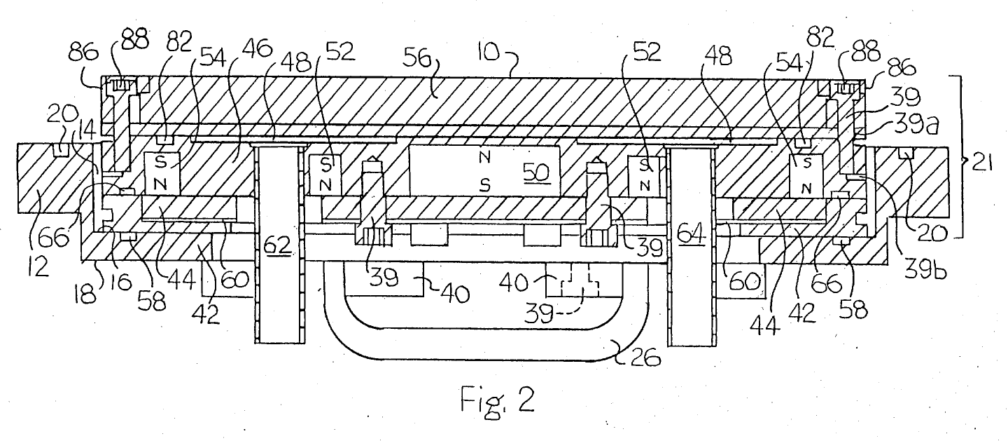

Referring to FIGS. 1 and 2, the mounting flange 12 includes connections for grab handles 26 to aid in moving the fully-assembled magnetron sputtering device 15. The mounting flange 12, in intimate contact with the vacuum chamber mounting flange 22, is at the same electrical potential as the chamber mounting flange 22 and is electrically isolated from the cathode 21 by an insulator 42. The cathode 21 generally includes a magnet base 44 positioned adjacent the insulator 42, a cooling well 46 positioned adjacent the magnet base 44, and a target 56 positioned adjacent the cooling well 46. The mating of the target 56 to the cooling well 46 is sealed by a second sealing member 82 forming a cooling channel 48, preferably having a depth of 0.060 units and a width of approximately 2 units, through which cooling fluid flows. An alternate embodiment replaces the second sealing member 82 with a welded membrane that encloses the cooling channel 48 to contain the cooling fluid. The cooling channel 48 is supplied and relieved of cooling fluid through pipes 62, 64 welded in place to the cooling well 46 to provide a liquid-tight seal. The cooling well preferably allows a target density of about 500 Watts per unit squared, without damage.

As shown in FIGS. 1 and 2, a circular target clamp 86 is removably attached to the target 56, allowing faster target 56 changes. To further reduce the time necessary for target 56 change, the target clamps 86 feature keyhole slots 88. This allows the target clamps 86 to be removed without completely removing fasteners, such as retaining screws 39. The target clamps 86 are attached to the cooling well 46 by screws 39. The target clamps 86 include counterbores to recess the head of the screws 39. The tapped holes 39a for the screws 39 include cross drills 39b to vent the bottoms of the tapped holes eliminating the need for vented screws.

As shown in FIG. 1, the magnetron sputtering source is also held together by fasteners, such as screws 39, with selected screws 39 extending through insulated end caps 40. The screws 39 hold together the mounting flange 12, insulator 42, and cooling well 46. Third sealing member 58 and fourth sealing member 66 are compressed to provide an airtight seal. The insulator 42 isolates electrically hot parts, such as the cooling well 46, from the mounting flange 12 and is preferably formed from a single material, such as DELRIN or TEFLON. The magnet base 44 is attached to the cooling well 46 by screws 39. A hollow notch 60 is provided to allow variances in the magnet base 44 thickness and to help ensure compression of the sealing members 58, 66 when the screws 39 are tightened.

With continuing reference to FIG. 1, the cathode 21 is powered via one or more power connectors 28, manufactured by Warner Electric, each having an outer insulating cover 30 and an inner copper electrical lead 29, which is connected to an electrical power supply 31. The power connector 28 mates to an electrically-conductive post 32 which is mated to the cooling well 46 via a screw connection and held in place with a lock-nut 38. The power connectors 28 can provide 10-20 kilowatts of electrical power to the cathode 21 portion of the magnetron sputtering device 15. Larger sizes of magnetron sputter sources can utilize a plurality of power connectors 28 to provide sufficient power to the cathode 21.

The cooling well 46 is designed to ensure turbulent flow of the cooling fluid at a recommended coolant flow. It normally exhibits a temperature increase of 15-25° C. between the coolant inlet orifice 62 and the coolant outlet orifice 64. Stainless steel and copper are acceptable materials for the cooling well 46, but stainless steel is preferred because it exhibits superior corrosion resistance compared to copper. Efficient cooling allows the magnetron sputtering device 10 to run at higher operating power densities (500 Watts per unit squared is equivalent to 20 kW on a 7 unit diameter target) for extended periods and reduces the occurrence of magnet damage (magnet degaussing), target melting, and excessive material expansion or deformation. Since the cooling channel 48 is flat and wide, it effectively forms a heat shield between the hot target 56 and the magnet arrays 50, 52, 54, protecting the magnets from the most direct heat source which maintains the magnet temperature well below the de-gauss temperature. Additionally, stainless steel is more durable for and extends the useful life of the cathode 21.

The first (inner primary magnet), second (inner winglet magnet), and third (outer primary magnet) magnet arrays 50, 52, 54 are adjacent to the magnet base plate 44 and enclosed within the cooling well 46. As best shown in FIG. 5, each magnet array 50, 52, 54 is preferably formed from a single, circular, integrally-formed magnet, with the second and third magnet arrays 52, 54 forming hollow center portions 68. However, due to the expense of solid circular magnets, circular-shaped magnets may be approximated by using smaller, non-circular magnets 70. The magnets forming each of the magnet arrays 50, 52, 54 are preferably rare earth magnets, creating a tangential magnetic field strength of approximately 400 Gauss over a 4 unit diameter, ⅛ unit thick radial target 56; or 150 Guass over a 7 unit diameter, ⅝ unit thick radial target. These values are estimated in accordance to the formulas described by Goree and Sheridan in Applied Physics Letters, Volume 59, Number 9, pages 1052-1054, herein incorporated by reference in its entirety.

With continuing reference to FIG. 5, the first magnet array 50 is nested within the hollow center portion 68 of the second magnet array 52, and the first and second magnet arrays 50, 52 are nested within a hollow center portion 68 of the third magnet array 54. As shown in FIGS. 1-4, the north pole N of the first magnet array 50 is positioned adjacent the magnet base 44. Conversely, the south poles S of the second and third magnet arrays 52, 54 are positioned adjacent the magnet base 44. The reverse polarity orientation of the first and second magnet arrays 50, 52 helps prevent the first and second magnetic arrays 50, 52 from repelling each other and the individual magnets within the same array during assembly. Within this invention, the north and south polarities of all magnets within an array may be switched, and the same result would occur.

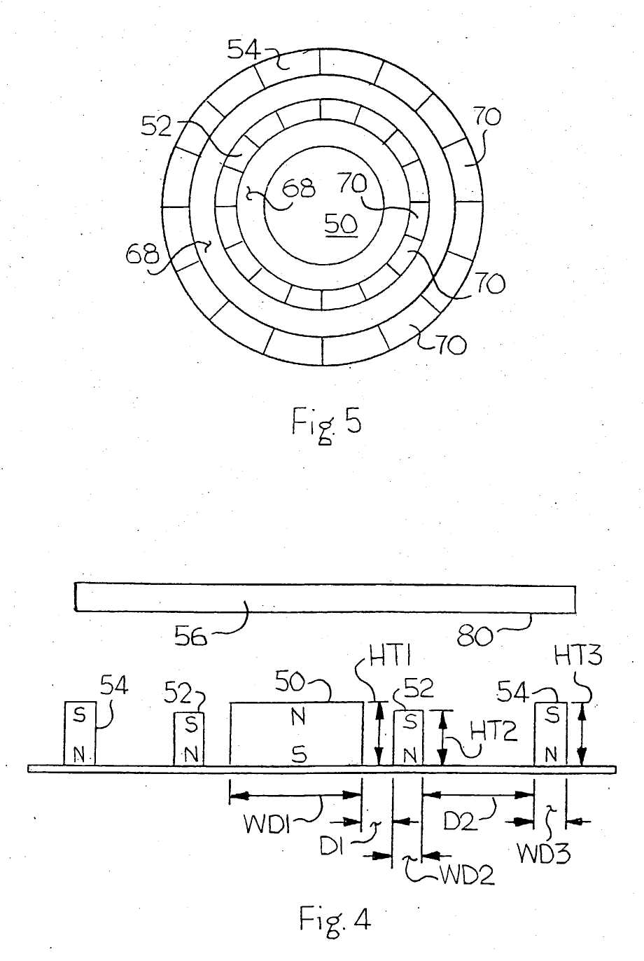

As shown in detail in FIG. 4, for a 7 unit target 56, the first magnet array 50 is positioned at a constant radial distance D1 of approximately 0.75 units from the second magnet array 52. The third magnet array 54 is positioned at a constant radial distance D2 of approximately 1.45 units from the second magnet array. The first magnet array 50 is preferably 0.50 units in height HT1 and 1.50 units in width WD1 when viewed in cross section. The second magnet array 52 is 0.40 units in height HT2 and 0.20 units in width WD2 when viewed in cross section. The third magnet array 54 is 0.40 units in height HT3 and 0.30 units in width WD3 when viewed in cross section. For a racetrack or oval design, a fourth (outer winglet magnet) magnet array may also be added, encompassing the first, second, and third magnet arrays 50, 52, 54.

FIG. 9 shows a plan or assembled view of the magnet array for a 7 unit diameter planar target having a first magnet array radius of approximately 0.75 units, a first inner radius of approximately 1.47 units, and a second inner radius of approximately 3.1 units. The second magnet array may include thirty-one magnets having dimensions of approximately 0.25 units by 0.2 units by 0.4 units and the third magnet array may include sixty-nine magnets each having dimensions of 0.28 units by 0.3 units by 0.4 units. The first and second magnet arrays may each have their magnetizing direction in the 0.4 unit direction.

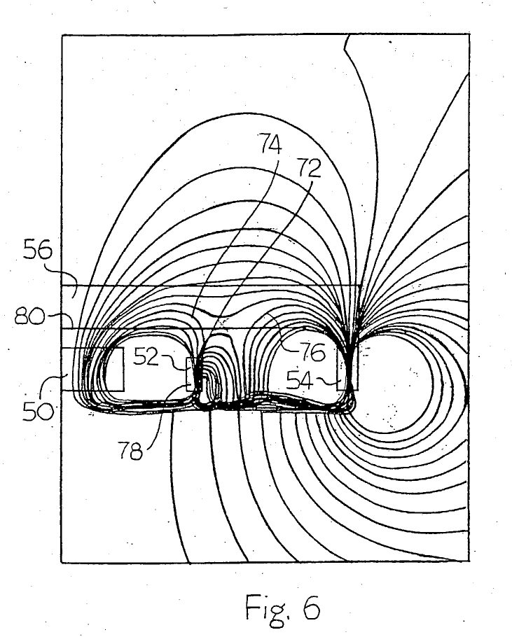

As shown in FIG. 6, the magnet array configuration according to the first embodiment of the present invention generally forms a magnetic pattern of flux lines and field strengths forming closed magnetic loop regions containing a first closed magnetic loop region 72, a second closed magnetic loop region 74, a third closed magnetic loop region 76, and a fourth closed magnetic loop region 78. The first, second, and third magnetic regions will, during the use of a target, have a portion of their loop going through the free surface of the target. This allows the loop to confine electrons near the surface of the target. The first closed magnetic loop region 72 has different behaviors for the flux lines within the loop. For example, the first magnetic loop region 72 may have magnetic field lines approximately parallel, perhaps less than 5 degrees, over approximately thirty percent of the free surface 10 of the target. The field strength of the first closed magnetic loop region over a portion of the free surface 10 of the target 56 is sufficient for ionization. Moreover, the first closed magnetic loop region may have a magnetic flux line pattern which exhibits an inflection, changing field curvature from convex to concave with respect to the magnet base 44. The flux lines closest to the second and third closed magnetic loop regions 74, 76 have a concave behavior near the center of the loop, and the lines furthest from the second and third closed magnetic loop regions are convex in the same region. The fourth magnetic region 78 does not necessarily confine plasma and, therefore, does not need to be in the target 56. Moreover, the fourth closed magnetic loop region 78 does not intersect the free surface 10 of the target 56.

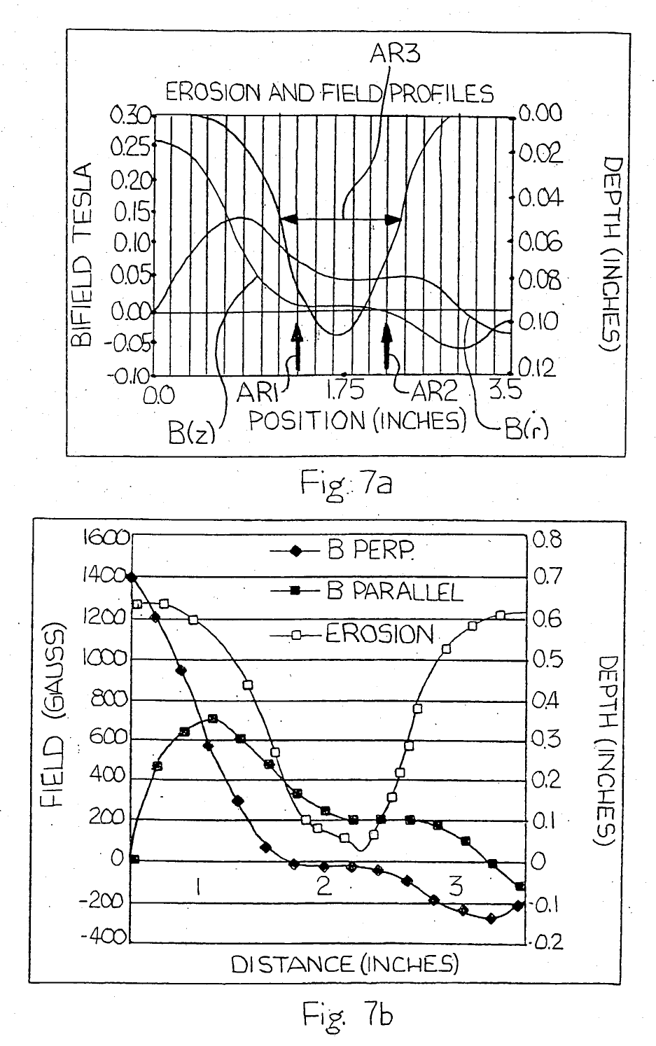

The initial magnetic field distribution for a flat target of the magnet configuration array according to the first embodiment of present invention is shown generally in FIG. 7a. The B(z) component of the magnetic field and B(r) component of the magnetic field were measured with a Lakeshore Cryogenics Gaussmeter. FIG. 7a shows that the B(z) component of the magnetic field approaches zero over a region beginning at approximately 1.5 units and continues to stay at or near zero up to approximately 2.25 units. The difference (0.75 units) represents the full width half maximum of the erosion trough found on one side of the target 56 during sputtering. FIG. 7b also shows the depth of the erosion trough over the same erosion trough width, which in this case is approximately 0.56 units. The final eroded profile shows a 0.56 depth from a radius of 1.5 units to 2.37 units.

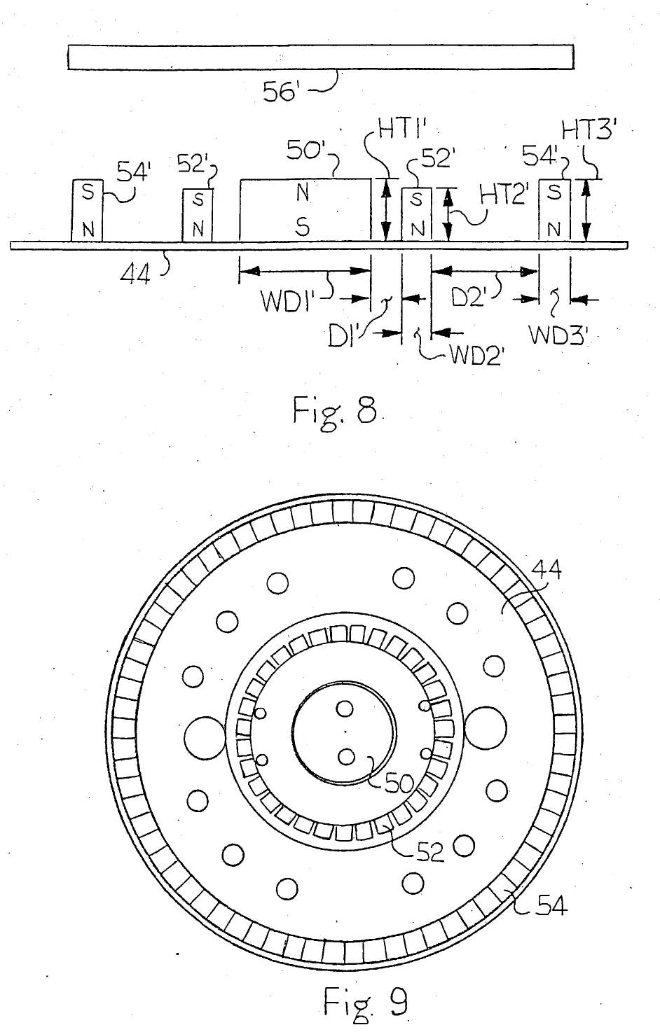

As shown in FIG. 8, other magnet array configurations are also contemplated, depending on the desired application. For a 4 unit radial target 56′, the first magnet array 50′ is spaced 0.085 units D1′ from the second magnet array 52′ and the second magnet array 52′ is spaced 0.893 units D2′ from the third magnet array 54′. The first magnet array 50′ is preferably a single magnet 1.0 units in width WD1′ and 0.5 units in height HT1′. The second magnet array 52′ is 0.142 units in width WD2′ and 0.375 units in height HT2′. The second magnet array is thirty-one equally-spaced magnets which allow for some space between magnets, allowing for the minor empirical trials to maximize utilization. The third magnet array 54′ is 0.16 units in width WD3′ and 0.50 units in height HT3′. The magnetic field is preferably 400 Gauss over the target 56.

A three-magnet array configuration reduces costs yet still produces high-target utilization of approximately 40 percent or more. Additionally, any natural, repulsive force between the first and second arrays, which are positioned closely together, is effectively eliminated by the magnetic orientation of the arrays, the relative sizes of the magnets in the two arrays, and the relative distances between the arrays. This makes the present invention easier to assemble and repair.

A four-magnet array configuration may be used to help shape the magnetic field, especially at larger cathode sizes. In a four-magnet array configuration, a fourth magnet array is positioned adjacent to the third magnetic array. The fourth magnetic array preferably has a north polarity and an opposite south polarity, wherein the magnetic pattern further includes the fourth closed-magnetic loop region formed between the third magnet array, the magnet return also includes the fourth magnet array, and the third closed-magnetic loop region also goes through the fourth magnet array.

These magnet designs will show superior erosion when balanced correctly. The present invention preferably produces magnetic flux lines approximately parallel to as much of the free target surface as possible.

The present invention can also include quick change target release clamps that help reduce target change times, thereby reducing manufacturing down time. Moreover, as shown in FIGS. 1-3, the number of sealing members is minimized, prolonging cathode life.

The cathode may also include an efficient cooling well for cooling the target. This cooling well may be set up such that the Reynolds number for the cooling fluid is above 5,000 for turbulent flow, thereby increasing the heat transfer coefficient. The cooling may be directly against the target or through a thin copper membrane. The cooling may be as high as 500 watts per unit squared of target surface. The cooling well may be fabricated from stainless steel in order to afford better thread forming.

The invention has been described with reference to the preferred embodiments. Obvious modifications and alterations will occur to others upon reading and understanding the preceding detailed description. For example, the specified sizes and distances between magnets may be any ratio of the above values in any units. Also, the magnet array configuration may have more magnet arrays (4, 5, 6, etc.) for larger cathodes. It is intended that the invention be construed as including all such modifications and alterations insofar as they come within the scope of the appended claims or the equivalents thereof.

I claim:

1. A magnet configuration for a magnetron sputtering device comprising:
a magnet base having a perimeter;
a first permanent magnet array positioned adjacent to the magnet base;
a second permanent magnet array positioned adjacent to the first magnet array; and
a third permanent magnet array positioned adjacent to the second magnet array,
wherein the first, second, and third magnet arrays each have a north polarity and an opposite south polarity, and at least one of said second or third permanent magnet arrays has a smaller height than the first permanent magnet array.

2. The magnet configuration for a magnetron sputtering device as claimed in claim 1, wherein
the south polarity of the first magnet array is positioned adjacent to the magnet base;
the north polarity of the second magnet array is positioned adjacent to the magnet base;
the north polarity of the third magnet array is positioned adjacent to the magnet base; and
the magnet base has a magnetic permeability greater than one and forms a magnetic return.

3. The magnet configuration for a magnetron sputtering device as claimed in claim 2, further comprising:
a fourth magnet array having a north polarity and an opposite south polarity,
wherein the south polarity is positioned adjacent to the magnet base.

4. A magnet configuration for a magnetron sputtering device comprising:
a target having a free surface, a bottom, and a useable lifetime;
a magnet base having a perimeter positioned adjacent to the target;
a first permanent magnet array positioned adjacent to the magnet base;
a second permanent magnet array positioned adjacent to the first magnet array; and
a third permanent magnet array positioned adjacent to the second magnet array,
wherein at least one of said second or third magnet arrays has a smaller cross-section than said first magnet array,
the first, second, and third magnet arrays each have a north polarity and an opposite south polarity,
the south polarity of the first magnet array is positioned adjacent to the magnet base,
the north polarity of the second magnet array is positioned adjacent to the magnet base,
the north polarity of the third magnet array is positioned adjacent to the magnet base, and
the magnet base has a magnetic permeability greater than one and forms a magnetic return which further forms a magnetic pattern of flux lines and field strengths forming closed magnetic loop regions, wherein the magnetic pattern comprises:
a first, closed magnetic loop region formed between the first magnet array and the second magnet array;
a second, closed magnetic loop region formed between the first magnet array and the third magnet array;
a third, closed magnetic loop region formed between the second magnet array and the magnetic return;
a fourth, closed magnetic loop region formed between the third magnet array and the magnetic return; and
a first magnetic field region formed by the transitions between the magnetic loop regions, which forms a null point.

5. The magnet configuration for a magnetron sputtering device as claimed in claim 4, wherein
the null point is located near or below the bottom of the target.

6. The magnet configuration for a magnetron sputtering device as claimed in claim 4, wherein
the null point is located near or below the free surface of the target and the end of the useful lifetime of the target.

7. The magnet configuration for a magnetron sputtering device as claimed in claim 4, further comprising:
a fourth magnet array positioned adjacent to the third magnetic array, the fourth magnet array having a north polarity and an opposite south polarity, wherein the magnetic pattern further includes the fourth closed magnetic loop region formed between the third magnet array;
the magnet return also includes the fourth magnet array; and
the third, closed magnetic loop region also goes through the fourth magnet array.

8. The magnet configuration as claimed in claim 4, wherein the first closed magnetic loop region has magnetic field lines approximately parallel over at least thirty percent of the free surface; and
the field strength of the first, closed magnetic loop region over a portion of the free surface of the target is sufficient for ionization.

9. The magnet configuration as claimed in claim 8, wherein the approximately parallel field lines have an angle of less than 5 degrees.

10. The magnetic configuration as claimed in claim 4, wherein the fourth, closed magnetic loop region does not intersect the free surface of the target.

11. The magnetic configuration as claimed in claim 4, wherein the first, closed magnetic loop region has a magnetic flux line pattern which exhibits an inflection, changing field curvature from convex to concave with respect to the magnet base.

12. The magnetic configuration as claimed in claim 4, wherein the free target surface is a non-planar surface.

13. A magnetron sputtering cathode assembly comprising:
a target;
a cooling well positioned adjacent to the target;
a permanent magnet array positioned adjacent the cooling well; and
an electrically-insulating frame.

14. The magnetron sputtering cathode as claimed in, claim 13, wherein the magnetron sputtering cathode further comprises:
a mounting flange which forms a vacuum seal allowing a pressure ratio of at least 10⁶ torr when attached to an appropriate chamber.

15. The magnetron sputtering cathode as claimed in claim 14, wherein the mounting flange is recessed within the chamber.

16. The magnetron sputtering cathode as claimed in claim 13, wherein the magnet array is partially recessed within the cooling well.

17. The magnetron sputtering cathode as claimed in claim 13, wherein the permanent magnet array consists of:
a first magnet array;
a second magnet array;
a third magnet array; and
a magnet base having a perimeter.

18. The magnetron sputtering cathode as claimed in claim 13, wherein the permanent magnet array consists of:
a first magnet array;
a second magnet array;
a third magnet array;
a fourth magnet array; and
a magnet base having a perimeter.

19. The magnetron sputtering cathode as claimed in claim 17, wherein
the target has a free surface;
the first, second, and third magnet arrays each have a north polarity and an opposite south polarity;
the south polarity of the first magnet array is positioned adjacent to the magnet base;
the north polarity of the second magnet array is positioned adjacent to the magnet base; and
the north polarity of the third magnet array is positioned adjacent to the magnet base.

20. The magnetron sputtering cathode as claimed in claim 19, wherein the first magnet array is in a middle portion of the magnet base;
the third magnet array is at or near the perimeter of the magnet base; and
the second magnet array is positioned between the first magnet array and the third magnet array.

21. The magnetron sputtering cathode as claimed in claim 13, wherein
the cooling well defines a channel;
the channel forms one or more flow paths between an inlet and an outlet port;
the channel is near the target; and
the cooling channel is designed to achieve turbulent flow by having a Reynolds number greater than 5,000.

22. The magnetron sputtering cathode as claimed in claim 13, wherein the cooling well allows a target power density of about 500 W/in² or greater, without damage.

23. The magnetron sputtering cathode as claimed in claim 21, wherein the depth of the cooling channel is 0.060 units with a width of approximately 2 units.

24. The magnetron sputtering cathode as claimed in claim 17, wherein individual circular or rectangular magnets are used to approximate continuous rings for the magnet sets and the size of the individual magnets may be adjusted to account for shape factor effects.

25. The magnetron sputtering cathode as claimed in claim 16, wherein the first magnet array, the second magnet array, and third magnet array are isolated from the water channels.

26. The magnetron sputtering cathode as claimed in claim 16, wherein the insulating frame is undercut to ensure compression of a vacuum seal to the cooling well prior to contact with the magnet base plate.

27. The magnetron sputtering cathode as claimed in claim 14, wherein the mounting flange contains a seal positioned between the insulating frame and to the vacuum chamber.

28. The magnetron sputtering cathode as claimed in claim 16, wherein the pumping volume of the cathode is minimized.

29. The magnetron sputtering cathode as claimed in claim 27, wherein each magnet array is isolated from an evacuated region.

30. The magnetron sputtering cathode as claimed in claim 16, wherein the target is held to the cooling well via a target clamp defining keyhole slots to facilitate removal of the clamping mechanism.

31. The magnetron sputtering cathode as claimed in claim 16, in which the target and cathode symmetry is circular.

32. The, magnetron sputtering cathode as claimed in claim 16, in which the target and cathode symmetry is rectangular.

33. The magnetron sputtering cathode as claimed in claim 19, wherein the cathode is a round cathode;
the first magnet array is a single, center magnet at the middle portion of the magnet base;
the second magnet array is a plurality of rectangular magnets at a first inner radius; and
the third magnet array is a plurality of rectangular magnets at a second inner radius.

34. The magnetron sputtering cathode as claimed in claim 33, wherein the center magnet has a radius and the second magnet array is not a fully-packed set of magnets.

35. The magnetron sputtering cathode as claimed in claim 34, wherein
the center magnet radius is 0.75 units;
the first inner radius is 1.47 units; and
the second inner radius is 3.1 units.

36. The magnetron sputtering cathode as claimed in claim 33, wherein the second magnet array includes thirty-one magnets having dimensions 0.25 units by 0.2 units by 0.4 units and the third magnet array includes sixty-nine magnets having dimensions 0.28 units by 0.3 units by 0.4 units.

37. The magnetron sputtering cathode as claimed in claim 33, wherein the first magnet array and the second magnet array each have their magnetizing direction in the 0.4 units direction.
